(19) United States
(12) Patent Application Publication
(10) Pub. No.: US 2008/0150142 A1
(43) Pub. Date: Jun. 26, 2008

(54) Multilevel wiring, laminated aluminum wiring, semiconductor device and manufacturing method of the same

(75) Inventor: Masayoshi Saito, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/000,751

(22) Filed: Dec. 17, 2007

(30) Foreign Application Priority Data
Dec. 21, 2006 (JP) 2006-343846

(51) Int. Cl. H01L 23/52; H01L 21/4763

(52) U.S. Cl. 257/752; 438/633; 257/E21.495; 257/E23.141

(57) ABSTRACT

A contact plug is formed in a contact hole which is formed in an interlayer insulation film and then a barrier metal layer and a main wiring layer, which form a wiring layer in all, are formed on both of the interlayer insulation film and the contact plug. After a surface of the main wiring layer is flattened by means of CMP, an antireflection film is formed on the main wiring layer. After that, a resist pattern is formed on the antireflection film to pattern the wiring layer. Thus, it is possible to pattern the wiring layer finely without influence of unevenness caused by the contact plug located under the wiring layer.

This application is based upon and claims the benefit of priority from Japanese patent application No. 2006-343846, filed on Dec. 21, 2006, the disclosure of which is incorporated herein in its entirety by reference.

### BACKGROUND OF THE INVENTION

1. Field of the Invention

This invention relates to multilevel wiring used in a semiconductor device and, in particular, to a manufacturing method of multilevel wiring including a wiring layer made of aluminum or aluminum-based alloy.

2. Description of the Related Art

A related manufacturing method of multilevel wiring for a semiconductor device is roughly as follows.

At first, a first wiring layer is formed on a first interlayer insulation film and then the first wiring layer is patterned to form first wiring having a predetermined a wiring pattern. Next, a second interlayer insulation film is formed to cover the first wiring and then a surface of the second interlayer insulation film is flattened. Next, contact halls which reach the first wiring are formed at predetermined places in the second interlayer insulation film. Then, contact plugs are formed in the contact halls. The contact plugs are flattened so that upper surfaces have a level identical to that of a surface of the second interlayer insulation film. Next, a second wiring layer is formed on both of the second interlayer insulation film and the contact plugs. Subsequently, the second wiring layer is patterned to form second wiring. Thereafter, as the same manner, forming an interlayer insulation film, forming contact plugs and forming a wiring layer are repeated to form the multilevel wiring.

Such a method of multilevel wiring is disclosed in Japanese Unexamined Patent Application Publication No. H9-213699 (1997).

In addition, there is a case where an etching process for the interlayer insulation film surrounding the contact plug is performed to project an upper portion of the contact plug from a surface of the interlayer insulation film. This etching process aims at enlargement of a contact area between the contact plug and the wiring layer formed on the contact plug and at reduction of electric resistance between them.

Such a technique is disclosed in Japanese Unexamined Patent Application Publication No. 2002-319970.

### SUMMARY OF THE INVENTION

The related manufacturing method of the multilevel wiring employs etch back method or chemical mechanical polishing (CMP) method to form a contact plug. However, each of these methods slightly dishes an upper surface of the contact plug to form a concavity. That is, the upper surface of the contact plug, which is formed by the related manufacturing method, slightly becomes hollow as against a surface of an interlayer insulation film surrounding the contact plug. The hollow or concavity of the contact plug becomes deep as an area of the upper surface of the contact plug becomes large. Generally, the upper surface area of the contact plug becomes larger as a position of the contact plug becomes high in the multilevel wiring.

In a case where an upper part of the contact plug is projected from the surface of the interlayer insulation film surrounding the contact plug, there is necessarily a level difference around the contact plug (or a convexity of the contact plug).

The concavity and the convexity of the contact plug affect a wiring layer formed on the contact plug. The concavity and the convexity appearing in a surface of the wiring layer condense or diffuse exposure light which is applied to photo resist used for patterning the wiring layer. Consequently, they narrow scope of proper exposure requirements for the photo resist, reduce exposure accuracy and cause bad exposure. Thus, the concavity and the convexity formed in the surface of the wiring layer impede further miniaturization and higher integration of a semiconductor device.

As mentioned above, the related manufacturing method of multilevel wiring has a problem that it is difficult to advance further miniaturization and higher integration of a semiconductor device because a wiring layer is affected by a shape of a contact plug.

It is therefore an exemplary object of this invention to provide a manufacturing method of multilevel wiring which is capable of further finely patterning or processing of a wiring layer formed on a contact plug without influence of unevenness caused by a contact plug.

According to a first aspect of this invention, there is provided a manufacturing method of multilevel wiring which includes the steps of: forming a main wiring layer made of aluminum or aluminum-based alloy; flattening a surface of the main wiring layer by means of CMP method; and patterning the main wiring layer.

Because the surface of the main wiring layer is flattened, it is possible to finely pattern the main wiring layer later.

According to a second aspect of this invention, there is provided a manufacturing method of multilevel wiring which includes the steps of: forming a contact plug in a contact hole which is formed in an interlayer insulation film; forming a barrier metal layer on both of the interlayer insulation film and the contact plug; forming a main wiring layer made of aluminum or aluminum-based alloy on the barrier metal layer; flattening a surface of the main wiring layer by means of CMP method; and patterning the main wiring layer.

According to a third aspect of this invention, there is provided a manufacturing method of laminated aluminum wiring which includes the steps of: forming a barrier metal layer; forming a main wiring layer made of aluminum or aluminum-based alloy on the barrier metal layer; flattening a surface of the main wiring layer; forming a resist pattern on the main wiring layer; and patterning the main wiring layer by use of the resist pattern.

According to a fourth aspect of this invention, there is provided a manufacturing method of a semiconductor device which includes the steps of: forming a contact plug in a contact hole which is formed in an interlayer insulation film; etching the interlayer insulation film to project an upper portion of the contact plug from a surface of the interlayer insulation film; forming a barrier metal layer on both of the interlayer insulation film and the contact plug; forming a main wiring layer made of aluminum or aluminum-based alloy on the barrier layer; and flattening a surface of the main wiring layer by means of CMP method.

According to a fifth aspect of this invention, there is provided a manufacturing method of a semiconductor device which includes the steps of: forming a main wiring layer made of aluminum or aluminum-base alloy; measuring at least one reflectance of a surface of the main wiring layer and a film thickness of the main wiring layer; judging whether it is necessary to flatten the main wiring layer according to measurement result; flattening the surface of the main wiring layer when it is judged to be necessary.

### BRIEF DESCRIPTION OF THE DRAWINGS

FIG. 1 is a sectional view of an example of a semiconductor device to which this invention is applicable;

FIG. 2 is a flowchart for describing a manufacturing method of multilevel wiring according to a first embodiment of this invention;

FIG. 3 is a flowchart for describing processes subsequent to the processes shown in FIG. 2;

FIGS. 4A to 4F are local sectional views for describing the processes shown in FIG. 2;

FIGS. 5A to 5F are local sectional views for describing the processes shown in FIG. 3;

FIGS. 6A to 6F are local sectional views for describing a manufacturing method of multilevel wiring according to a second embodiment of this invention;

FIGS. 7A to 7F are local sectional views for describing a manufacturing method of multilevel wiring according to a third embodiment of this invention;

FIG. 8 is a flowchart for describing a manufacturing method of multilevel wiring according to a forth embodiment of this invention;

FIGS. 9A to 9F are local sectional views for describing the processes shown in FIG. 8;

FIGS. 10A to 10F are local sectional views for describing a manufacturing method of multilevel wiring according to a fifth embodiment of this invention;

FIG. 11 is a flowchart for describing a manufacturing method of multilevel wiring according to a sixth embodiment of this invention;

FIGS. 12A to 12C are local sectional views for describing the processes shown in FIG. 11;

FIG. 13 is a local sectional view for describing a manufacturing method of multilevel wiring according to a seventh embodiment of this invention;

FIGS. 14A to 14F are local sectional views for describing a manufacturing method of multilevel wiring according to an eighth embodiment of this invention; and

FIG. 15 is a flowchart for minutely describing processes preceding and succeeding a step S215 of FIG. 2 or a step S313 of FIG. 3;

### DESCRIPTION OF THE PREFERRED EMBODIMENTS

Hereinafter, preferred embodiments of this invention will be minutely described with reference to the drawings.

This invention is applicable to a manufacturing a dynamic random access memory (DRAM) and a flash memory which use aluminum-copper (AlCu) multilevel wiring and to a logic semiconductor device which is stacked on copper (Cu) wiring.

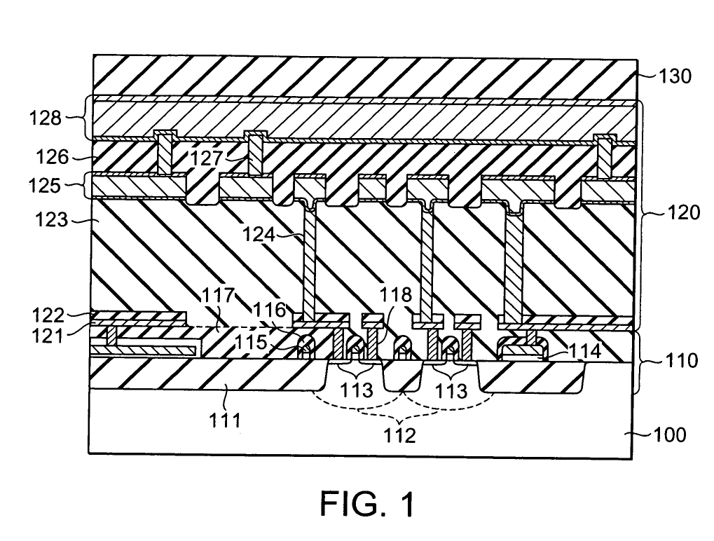

FIG. 1 is a sectional view of an example of a semiconductor device to which a manufacturing method of multilevel wiring (or laminated aluminum wiring) according to the invention is applicable. The illustrated semiconductor device has a semiconductor substrate 100, a transistor layer 110 formed on a semiconductor substrate 100 and a multilevel wiring layer 120 formed on the transistor layer 110. Moreover, a silicon dioxide (SiO₂) hard mask 130 is formed on the multilevel wiring layer 120.

The transistor layer 110 includes an element isolation region (or STI: shallow trench isolation) 111, wells 112, diffusion regions (source and drain regions) 113, a gate insulation film (not shown), a polysilicon layer 114, a gate metal layer 115, a silicon nitride (SiN) film 116, a first interlayer insulation film (SiO₂) 117 and first contact plugs 118.

On the other hand, the multilevel wiring layer 120 includes a first wiring layer 121, a silicon nitride (SiN) film 122, a second interlayer insulation film (SiO₂) 123, second contact plugs 124, a second wiring layer 125, a third interlayer insulation layer (SiO₂) 126, third contact plugs 127 and a third wiring layer 128.

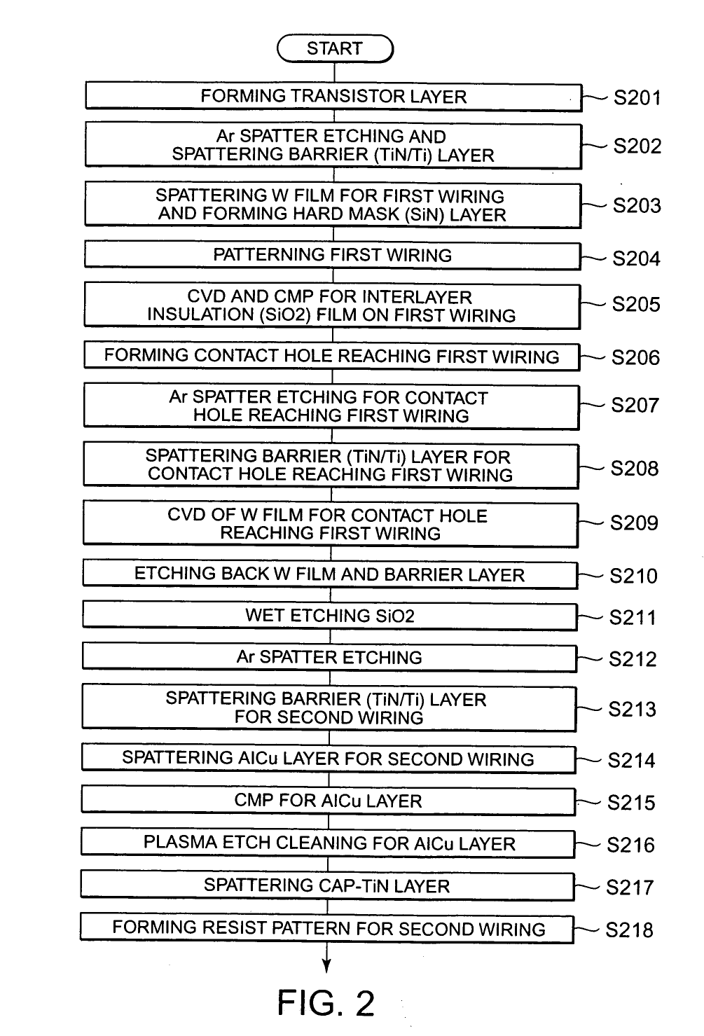

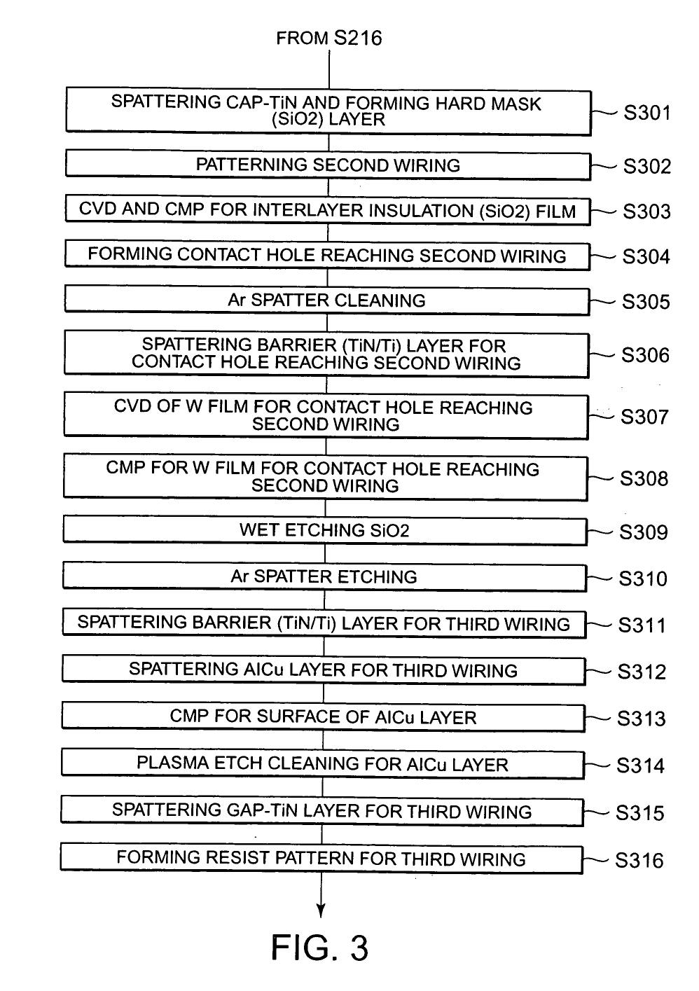

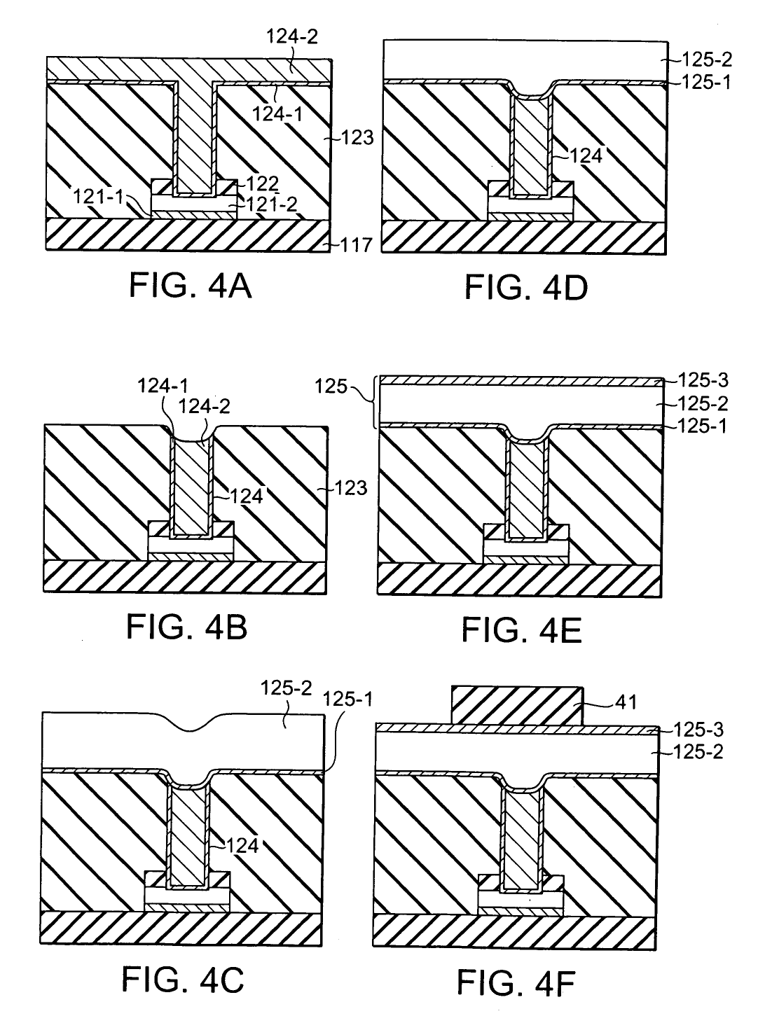

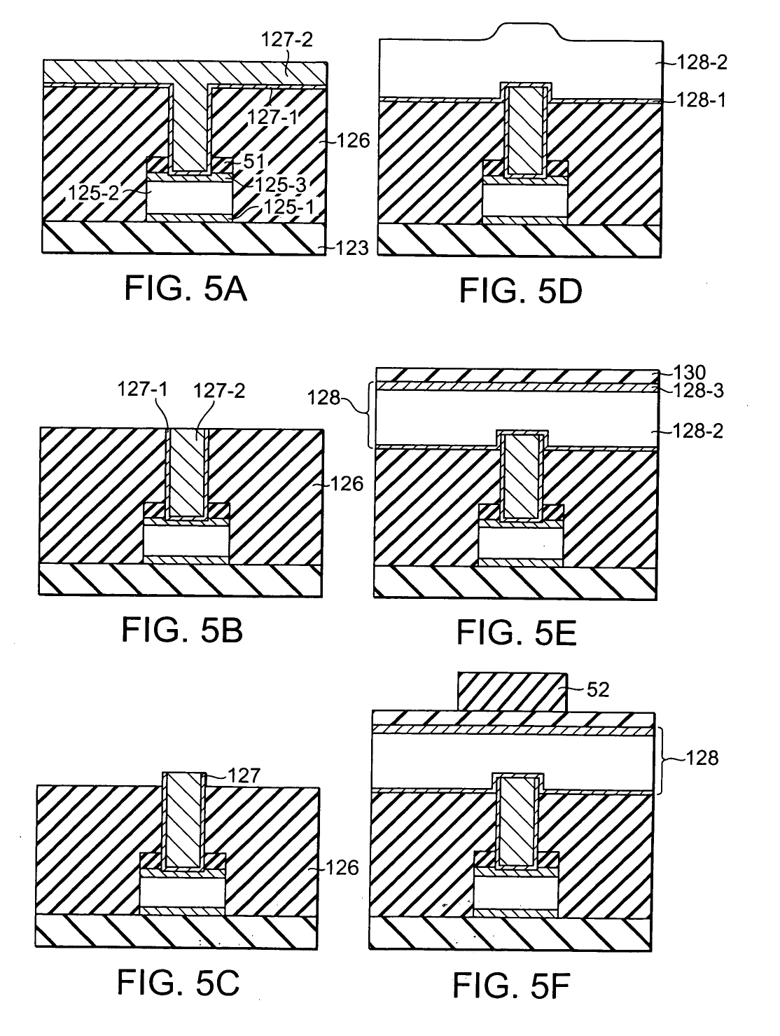

Next, the description will be made about a manufacturing method, which uses a manufacturing method of the multilevel wiring according to a first embodiment of this invention, for manufacturing the semiconductor device of FIG. 1 with reference to flowcharts of FIGS. 2 and 3 and local sectional views of FIGS. 4A to 4F and 5A to 5F.

At first, the transistor layer 110 is formed by a known method (Step S201). The formation of the transistor layer 110 includes formation of the element isolation region 111, the wells 112, the diffusion regions 113, the gate insulation film and the gate electrodes (or the polysilicon layer 114 and the gate metal layer 115), i.e. formation of MOS transistors. The formation of the transistor layer 110 further includes formation of the first interlayer insulation film 117, contact holes reaching to the diffusion regions 113 and to the gate metal film 115 and the first contact plugs 118 in the contact holes.

The first contact plugs 118 is formed by forming a TiN/Ti film as a barrier metal layer to cover exposed surfaces of the contact hales formed in the first interlayer insulation film 117, forming a tungsten (W) film to be embedded in the contact hales and performing etch back or chemical mechanical polishing (CMP). In this event, the etch back process or the CMP process is performed to make upper surfaces of the first contact plugs 118 the same level with a surface of the first interlayer insulation film 117. Confirmation of evenness of the surface of the sample (or judgment whether excess W and TiN/Ti films are removed to expose the surface of the first interlayer insulation film 117 outside or not) can be made by monitoring reflectance of light applied to the surface of the sample. Incidentally, the TiN/Ti film represents a laminated film of a TiN film and a Ti film, wherein TiN is stacked on the Ti film. Hereinafter, the symbol “/” represents such a laminated or stacked structure.

Next, sputter etching using argon (Ar) gas is performed to remove oxide films formed on surfaces of the first contact plugs 118 which are exposed in a surface of the transistor layer 110. Subsequently, a barrier metal layer (TiN/Ti laminated films or TIN single film) used for the first wiring layer 121 is formed by sputtering (Step 202).

Next, a tungsten (W) film also used for the wiring layer 121 is formed by directional sputtering method. Furthermore, the SiN film 122 is formed as a hard mask, which is used for patterning the first wiring layer 121, by a known method (Step S203).

Next, the SiN film 122 is patterned into a predetermined wiring pattern and the first wiring layer 121 is processed (or patterned) by using the patterned SiN film 122 as a mask. (Step S204).

Next, the second interlayer insulation film (SiO₂) 123 is formed by plasma chemical vapor development (PCVD) method and the surface thereof is flatten (or planarized) by CMP method (Step S205).

Next, contact holes which reach to the first wiring layer 121 are formed at predetermined places of the second interlayer insulation film 123 (Step S206). Subsequently, sputter etching using Ar gas is performed to remove oxide films formed on exposed surfaces, which are exposed at the bottoms of the contact hales, of the first wiring layer 121 (Step S207). Then, a barrier metal layer (TiN/Ti) used for the second contact plugs 124 is formed by sputter (Step S208) and a tungsten film also used for the second contact plugs 124 is formed by CVD (Step S209). FIG. 4A shows a local sectional view of the sample obtained by the processes of the steps S201-S209.

In FIG. 4A, one of the second contact plugs 124 and vicinity thereof is shown. The TiN film 121-1 and the W film 121-2, which form the first wiring layer 121, are 30 nm and 80 nm, respectively, in thickness, for example. The SiN film 122, for example, is 100 nm in thickness. The TiN film and the Ti film of the barrier metal 124-1, which used for the second contact plug 124, are 30 nm and 20 nm, respectively, in thickness, for example.

Next, as illustrated in FIG. 4B, the tungsten film 124-2 and the barrier metal layer 124-1 deposited on the second interlayer insulation film 123 are partly removed to remain embedded parts of them in the contact hole (Step S210). The remaining parts of the tungsten film 124-2 and the barrier metal layer 124-1 form the second contact plug 124. To remove the tungsten film 124-2 and the barrier metal layer 124-1 partly, etch back method which uses plasma etching or CMP method can be used.

For etch back method, plasma etching which uses halogen gas such as SF₆ can be used. In such a case, end of the etching can be controlled by monitoring luminescence intensity which is changed by tungsten and/or titanium included in etching gas. The upper surface of the tungsten film 124-2 embedded in the contact hole becomes concave because of etch back. The concavity becomes deep as an area of the upper surface of the tungsten film 124-2 becomes large. Because the second contact plug 124 is larger than the first contact plug 118 in diameter, the concavity of the second contact plug 124 is deeper than that of the first contact plug 118 and greatly affects upper layers in comparison with that of the first contact plug 118. Especially, there is an embedded portion having a width of about 2-4 μm in an alignment mark region for lithography.

Next, the second interlayer insulation film 123 is wet etched to clean the surface thereof (Step S211). After the sample is introduced into a sputter chamber, then degas processing is carried out. Then argon gas is introduced into the sputter chamber and an oxide film formed on the surface of the tungsten film 124-2 is removed by plasma etching (Step S212).

Subsequently, as illustrated in FIG. 4C, a titanium (Ti) film (e.g. 20 nm thickness) and titanium nitride (TiN) film (e.g. 30 nm thickness), which used for the second wiring layer 125, are formed in this order (Step S213). Here, the TiN film may be omitted. Alternatively AlCu film can be sputtered without depositing TiN/Ti. Then an aluminum-cupper (AlCu) film (aluminum including about 0.5 weight percents of Cu, 320 nm thickness) 125-2, which is also used for the second wiring layer 125 as a main wiring layer, is formed by sputter method (Step S214).

At a place corresponding to the second contact plug 124 in the surface of the AlCu film 125-2, a concavity is formed by influence of the shape of the upper surface of the second contact plug 124. When the AlCu film 125-2 is formed by sputter method, unevenness of a lower layer is somewhat amplified and appears in the surface thereof. If photo resist is formed on the AlCu film 125-2 having the concavity, exposure light applied to the photo resist is partly condensed and/or diffused at the concavity and exposure accuracy is reduced. Therefore, in this embodiment, the surface of the AlCu film 125-2 is flattened by CMP method (Step S215). The surface of the AlCu film 125-2 is polished in about 50 nm. Improvement of evenness of the AlCu film 125-2 can be monitored by measuring reflectance of the AlCu film 125-2 (with respect to ultraviolet light as the exposure light). The reflectance is low when the unevenness is large. The reflectance becomes high as the unevenness becomes small. It is possible to judge that the AlCu film has been flattened when the reflectance is equal to about 90% or more in consideration of a process margin.

After the surface of the AlCu film 125-2 is flattened, cleaning is performed for the flattened surface. FIG. 4D shows a local sectional view of the sample having the cleaned surface.

Next, the sample is introduced into a degas chamber of the sputter equipment and heated for about 60 seconds at about 100-200° C. Subsequently, a thin oxide film formed on the surface of the AlCu film 125-2 is removed by sputter etching using Ar gas (Step S216). In this event, temperature control is performed to maintain substrate temperature under about 300° C. Because the whole (upper) surface of the sample is covered by metal, it is to be noted that matching conditions (e.g. reflection of RF power) for the plasma etching is different from those of step S202 in which almost all of the surface is covered by an insulation film.

Next, as illustrated in FIG. 4E, a titanium nitride (TiN) film 125-3 (e.g. 25 nm thickness), which serves as an antireflection film, is formed by sputter method (Step S217). The TiN film 125-3 is referred as to a cap layer. In this event, it should be prevented that aluminum nitride is formed on the surface of the AlCu film 125-2. For instance, the TiN film 125-3 may be formed after a thin Ti film having 5 nm thickness is formed. Alternatively, reactive sputtering method having an initial process for forming TiN by introducing Ar gas and using a Ti target whose surface is azotized may be used.

Next, as illustrated in FIG. 4F, photo resist 41 is formed on the TiN film 125-3 and patterned (Step S218).

The TiN film 125-3 is laid to improve patterning accuracy of the photo resist 41. As mentioned above, the reflectance of the polished surface of the AlCu film 125-2 is equal to 90% or more in regard to the incident intensity of ultraviolet rays. On the other hand, the reflectance can be reduced under 20% when the TiN film 125-3 is formed. Photo resist formed on a surface of high reflectance material is exposed by not only incident exposure light but also reflected light from the surface of the high reflectance material. Consequently, if photo resist is directly formed on the polished AlCu film 125-2, it is affected by unevenness remaining in the surface of the AlCu film 125-2 and thereby reducing exposure accuracy. The TiN film 125-3 prevents from reducing such exposure accuracy and allows pattern forming with original accuracy of lithography (or with limit of miniaturization).

Before the photo resist 41 is formed, a silicon dioxide (SiO₂) hard mask may be formed on the TiN film 125-3 according to need. Hereinafter, the description will be advanced assuming that the SiO₂ hard mask (51 of FIG. 5A, e.g. 100 nm thickness) is formed (Step S301).

After the SiO₂ hard mask 51 is patterned by photolithography technique, the second wiring layer 125 is patterned (or processed) using the patterned SiO₂ hard mask (Step S302).

Next, the third interlayer insulation film (SiO₂) 126 is formed by CVD method and then the surface thereof is flattened by CMP method (Step S303).

Next, contact holes are formed in the third interlayer insulation film 126 (Step S304). The formation of the contact holes is performed to expose the TiN film of the cap layer 125-3 at the bottoms of the contact holes. Performing Ar sputter cleaning, oxide films formed on the exposed surfaces of the TiN film exposed at the bottoms of the contact holes are removed (Step S305).

Next, a barrier metal layer (TiN/Ti film or TiN film) for the third contact plug 127 is formed by sputtering (Step S306). A tungsten film for the third contact plug 127 is further formed by CVD method (Step S307). Thus, the contact holes formed in the third interlayer insulation film 126 are embedded.

FIG. 5A shows a local sectional view of the sample obtained by step S307. FIG. 5A shows one of the third contact plug 127 and vicinity thereof. In FIG. 5A, a contact hole is formed to penetrate the third interlayer insulation film 126 and the SiO₂ hard mask 51. A barrier metal 127-1 used for the third contact plug 127 is formed to contact with the cap TiN film 125-3 exposed at the bottom of the contact hole. A tungsten film 127-2 is embedded in the contact hole. Because the barrier metal layer 127-1 is formed to contact the TiN film 125-3 at the bottom of the contact hole in this embodiment, the barrier metal layer 127-1 may consists of a single layer TiN film.

Next, the tungsten film 127-2 for the third contact plug 127 is partly removed by CMP (Step S308) to expose the third interlayer insulation film 126 as illustrated in FIG. 5B.

Subsequently, the third interlayer insulation film 126 is wet etched (Step S309) to project the upper portion of the third contact plug 127 from the surface of the third interlayer insulation film 126 surrounding the third contact plug 127 as illustrated in FIG. 5C.

Next, Ar sputter etching is performed to remove an oxide film formed on the surface of the third contact plug 127 (Step S310). Then, as illustrated in FIG. 5D, a barrier metal layer (TiN/Ti) 128-1 for a third wiring layer 128 is formed by sputter (Step S311) and an AlCu film 128-2 is formed by sputter (Step S312). The AlCu film 128-2 serves as a main wiring layer of the third wiring 128. As the barrier metal layer 128-1, a Ti film of 20 nm thickness and a TiN film of 30 nm thickness, for example, are formed in this order. Moreover, the AlCu film 128-2 is formed to have a thickness of 600 nm, for example.

At the surface of the AlCu film 128-2, a convexity is affected by the third contact plug 127. The AlCu film 128-2 is polished by CMP to remove the convexity (Step S313).

Subsequently, the AlCu film 128-2 is cleaned by plasma etching to remove an oxide film formed on the AlCu film 128-2 (Step S314). Similarly as for Step S216, temperature control is performed to maintain substrate temperature under 300° C. and plasma etching is performed under matching conditions for a case where the whole surface is covered by metal.

Next, as illustrated in FIG. 5E, a TiN cap film 128-3 is formed by sputter (Step S315). Further, an SiO₂ hard mask 130 is formed by CVD according to need. The SiO₂ hard mask 130 may be omitted if unnecessary.

After that, as illustrated in FIG. 5F, a resist pattern 52 is formed to pattern the third wiring layer 128 (Step S316).

In this manner, the semiconductor device as shown in FIG. 1 can be manufactured. Afterwards, the third wiring layer is processed by a known method and a protective layer or a fourth and subsequent wiring layers is formed.

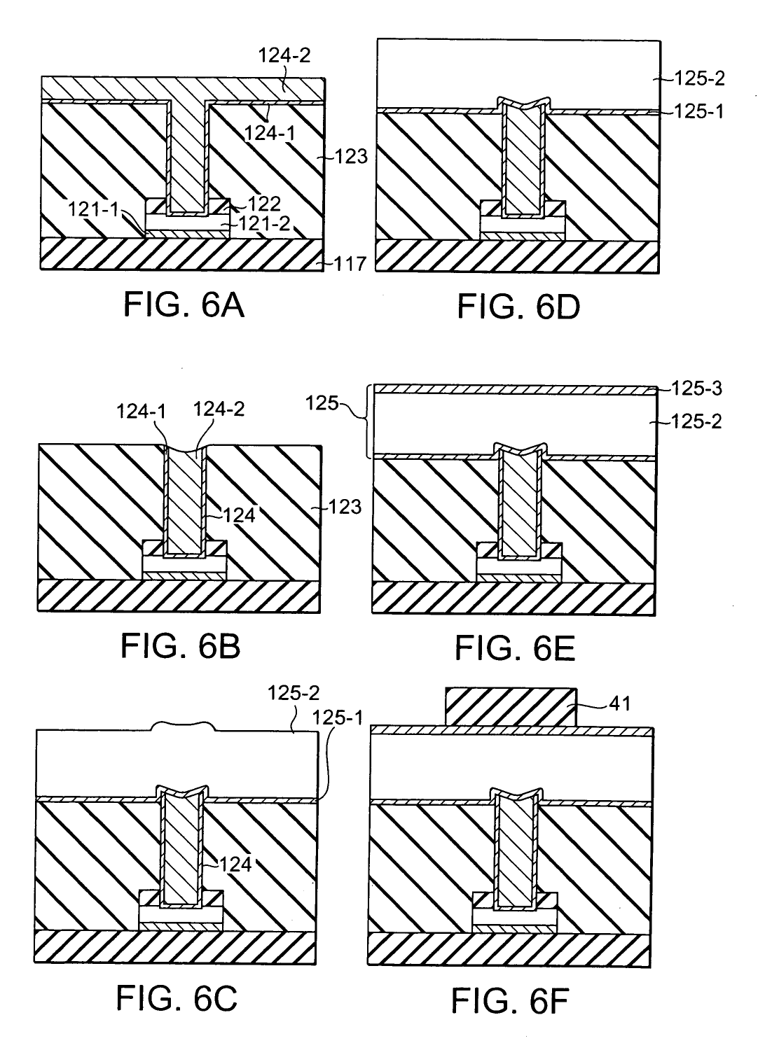

Next, the description will be made about a method for manufacturing multilevel wiring according to a second embodiment of this invention with reference to FIGS. 6A to 6F. Here, FIGS. 6A to 6F correspond to FIGS. 4A to 4F, respectively.

The method of manufacturing the multilevel wiring according to the second embodiment is almost the same as the method according to the first embodiment. However, in the second embodiment, the wet etching in step S211 is performed so that the upper portion of the second contact plug 124 is projected from the surface of the second interlayer insulation film 123.

Because the upper portion of the second contact plug 124 is projected from the surface of the second interlayer insulation film 123, the TiN/Ti film 125-1 for the second wiring layer is contact not only the upper surface of the second contact plug 124 but also a part of the peripheral surface of the second contact plug 124 as illustrated in FIG. 6C. Hereby, contact area between the second contact plug 124 and the second wiring layer 125 is increased and electric contact resistance between them is reduced.

In addition, as also shown in FIG. 6C, a convexity is formed at the surface of the AlCu film 125-2 for the second wiring layer 125 by influence from projection of the second contact plug 124. Similarly as for the first embodiment, the surface of the AlCu film 125-2 is polished by CMP method and thereby the convexity is removed. FIG. 6D shows a state after the surface of the AlCu film 125-2 is flattened.

After that, similarly as for the first embodiment, the TiN film 125-3 is formed on the flattened AlCu film 125-2 as shown in FIG. 6E. Furthermore, a resist pattern 41 is formed as shown in FIG. 6F.

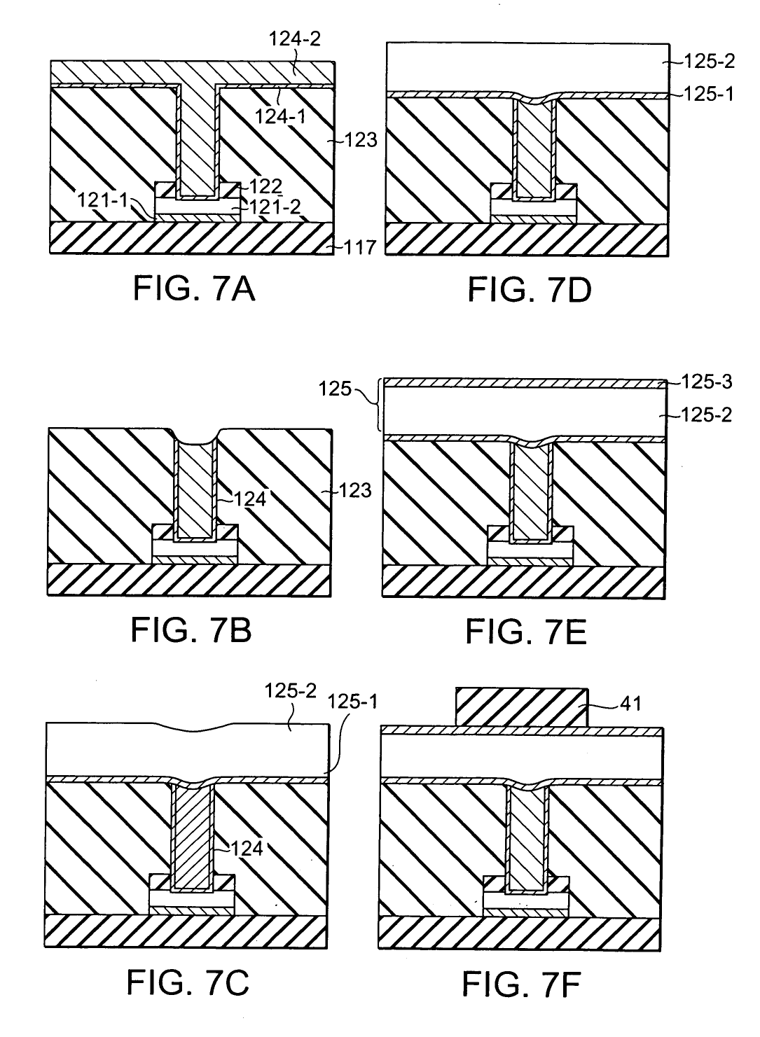

Next, the description will be made about a method for manufacturing multilevel wiring according to a third embodiment of this invention with reference to FIGS. 7A to 7F.

FIGS. 7A to 7F correspond to FIGS. 4A to 4F, respectively.

The method of manufacturing the multilevel wiring according to the third embodiment is almost the same as the method according to the first embodiment. However, in the third embodiment, etch back for the tungsten film 124-2 in step S210 is strongly performed and thereby reducing the concavity formed at the upper surface of the second contact plug 124 as understood from FIGS. 7B and 7C. In addition, the wet etching for the second interlayer insulation film 123 in step S211 is performed to make the surface of the second interlayer insulation film 123 almost the same level with the upper surface of the second contact plug 124 as understood from FIG. 7C. Hereby amount of CMP for the AlCu film is reduced.

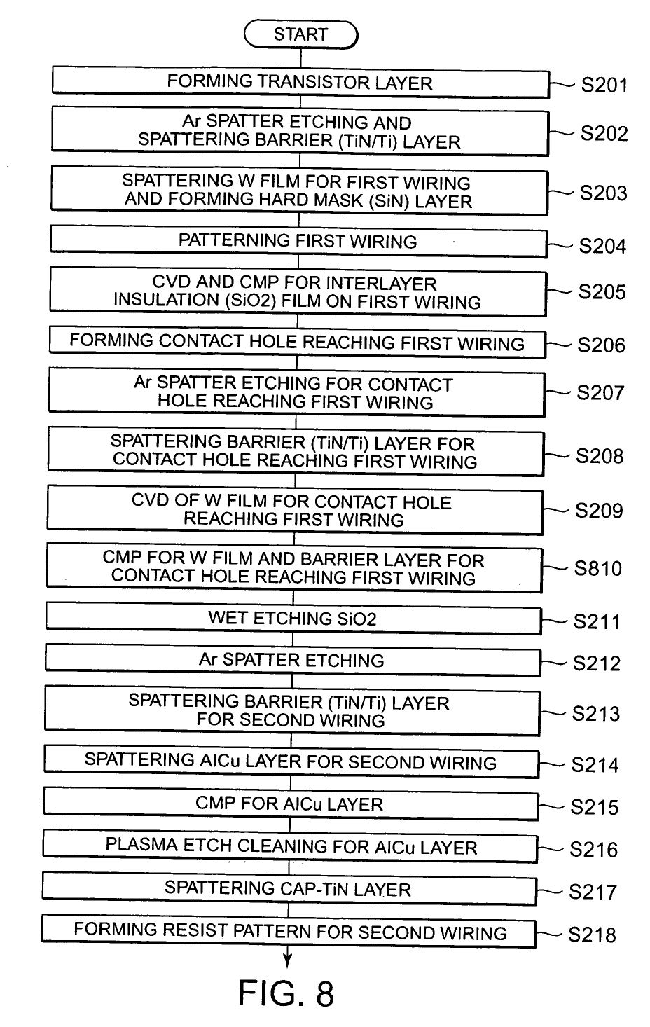

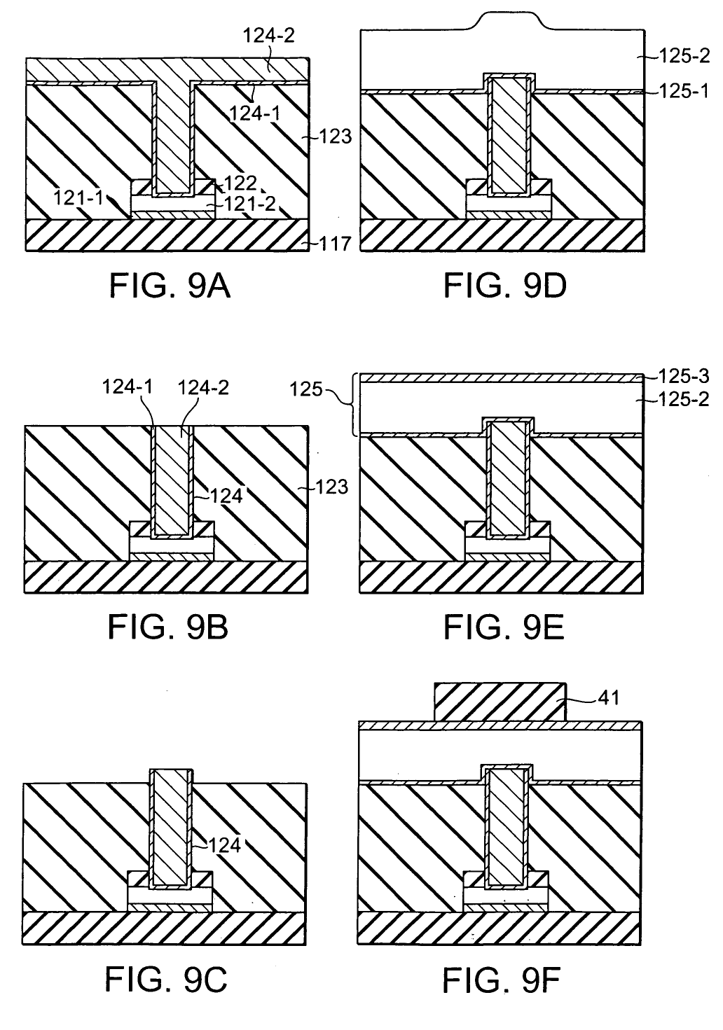

Next, the description will be made about a method for manufacturing multilevel wiring according to a fourth embodiment of this invention with reference to FIGS. 8 and 9A to 9F.

A flowchart of FIG. 8 corresponds to that of FIG. 2. FIGS. 9A, 9B, 9D, 9E and 9F correspond to FIGS. 6A, 6B, 6C, 6E and 6F, respectively.

The method of manufacturing the multilevel wiring according to the fourth embodiment is almost the same as the method according to the second embodiment. However, in the fourth embodiment, CMP of step S810 is performed in place of the etch back for the tungsten film 124-2 in step S210. FIG. 9B shows a state after polish of step S810.

After that, similarly as for the second embodiment, the second interlayer insulation film 123 is etched back to project the upper portion of the second contact plug 124 from the surface of the second interlayer insulation film 123 as shown in FIG. 9C. Then the second wiring layer 125 and a resist pattern 41 are formed as shown in FIGS. 9E and 9F.

According to this embodiment, the contact area between the second contact plug 124 and the second wiring layer 125 is increased and electric contact resistance between them is reduced.

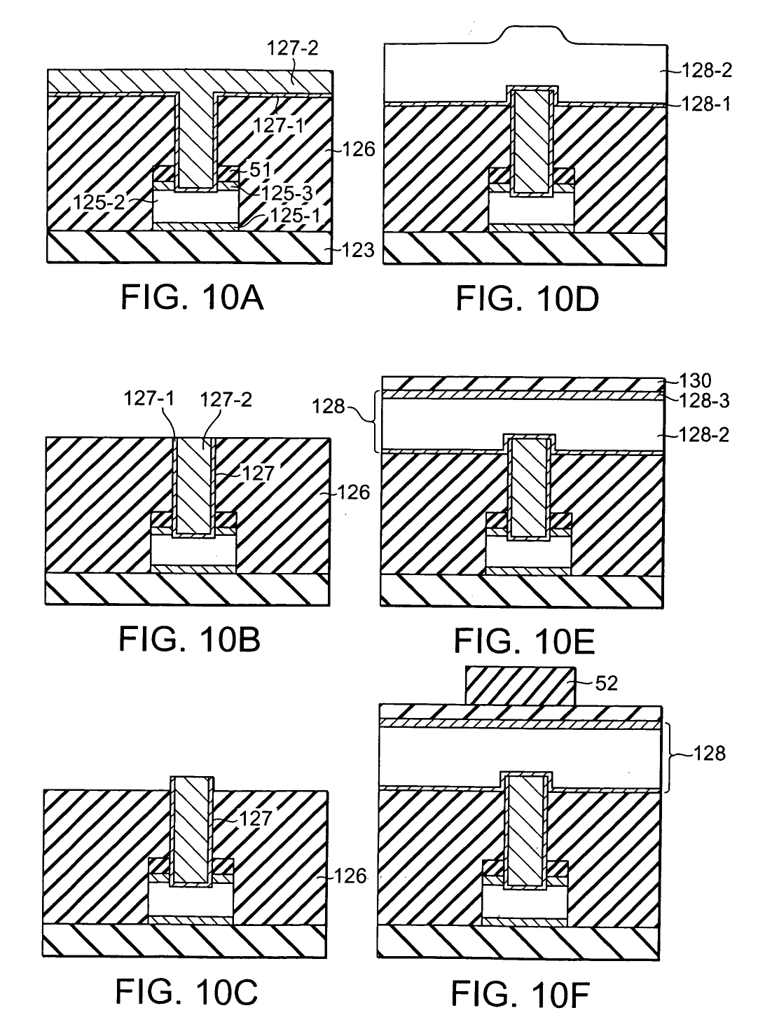

Next, the description will be made about a method for manufacturing multilevel wiring according to a fifth embodiment of this invention with reference to FIGS. 10A to 10F.

FIGS. 10A to 10F correspond to FIGS. 5A to 5F, respectively.

The method of manufacturing the multilevel wiring according to the fifth embodiment is almost the same as the method according to the first embodiment. However, in the fifth embodiment, formation of the contact hole is performed so that the contact hole reaches the AlCu film 125-2 as understood from FIG. 10A.

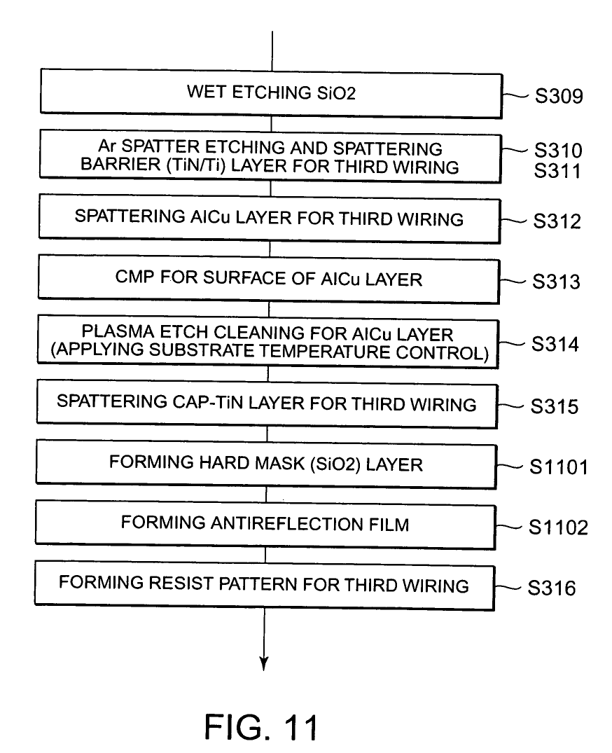

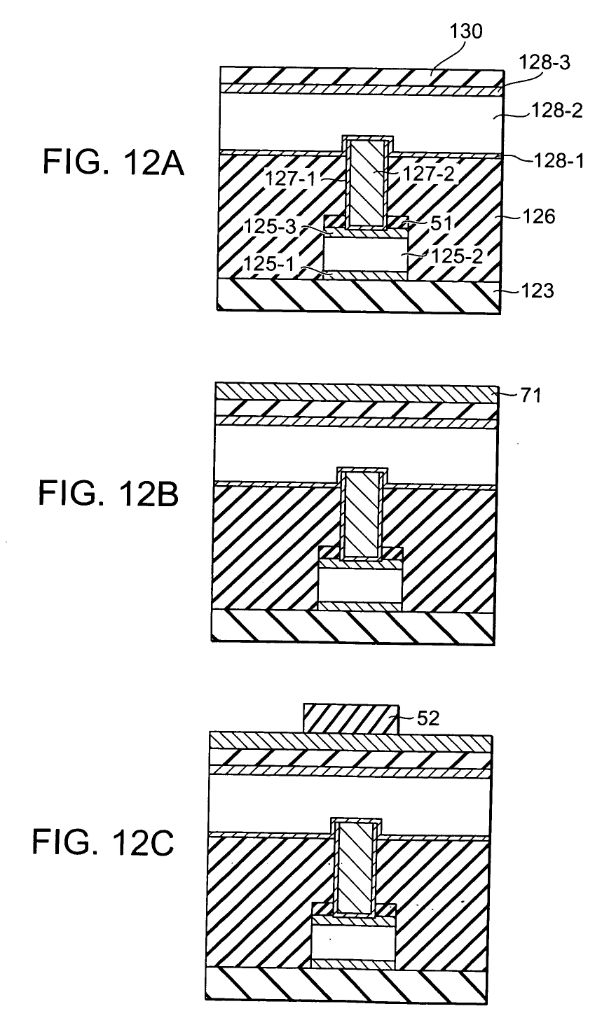

Next, the description will be made about a method for manufacturing multilevel wiring according to a sixth embodiment of this invention with reference to FIGS. 11 and 12A to 12F.

A flowchart of FIG. 11 corresponds to steps on and after step S309 of FIG. 3. FIG. 12A corresponds to FIG. 5E. FIGS. 12B and 12C are local sectional views of states of a sample processed by steps following the step of FIG. 12A.

In this embodiment, similarly as for the first embodiment, the third insulation film 126 is etched to clean the surface thereof and then the upper portion of the third contact plug 127 is projected from the surface of the third interlayer insulation film 126 (Step S309, see FIG. 5C). Subsequently, after Ar sputter etching is performed to remove the surface oxide film of the third contact plug 127, the barrier metal layer 128-1 and the AlCu film 128-2 are formed (Step S310-S312, see FIG. 5D). The AlCu film 128-2 is flattened by CMP method (Step S313). Further, the AlCu film 128-2 is cleaned by plasma cleaning to remove the oxide film on the surface thereof (Step S314). Then, the TiN cap film 128-3 is formed by sputtering (Step S315) and the SiO₂ hard mask is formed (Step S1101). FIG. 12A shows a local sectional view of the sample after step S1101.

After that, as shown in FIG. 12B, an antireflection film 71 is formed on the SiO₂ hard mask by coating or laying (Step S1102) and a resist pattern is further formed thereon (Step S316).

According to this embodiment, because the surface of the AlCu film 128-2 is flattened, unevenness of the surface of the SiO₂ hard mask which is formed afterwards and of the surface of the coating-type antireflection film 71 under the resist 52 can be reduced. In a case where the AlCu film 128-2 is not flattened, a corresponding part of the coating-type antireflection film 71 is reduced in thickness by influence of projection of the third contact plug 127. Therefore, there is a possibility that enough antireflection effect is not obtained.

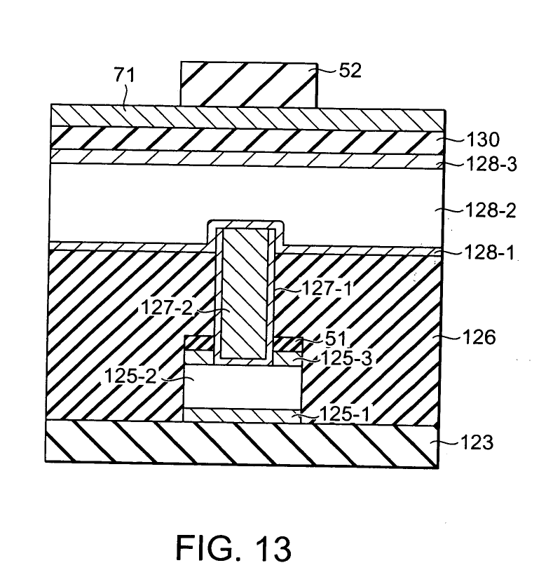

Next, the description will be made about a method for manufacturing multilevel wiring according to a seventh embodiment of this invention with reference to FIG. 13.

In this embodiment, similarly as for the fifth embodiment, the contact hole is formed to reach the AlCu film 125-2. Furthermore, similarly as for the sixth embodiment, the coating-type antireflection film 71 is formed on the SiO₂ hard mask 130.

According to this embodiment, because the AlCu film 128-2 is flattened after formation thereof, it is possible to improve the evenness of the SiO₂ hard mask and the coating-type antireflection film 71 which are formed afterwards.

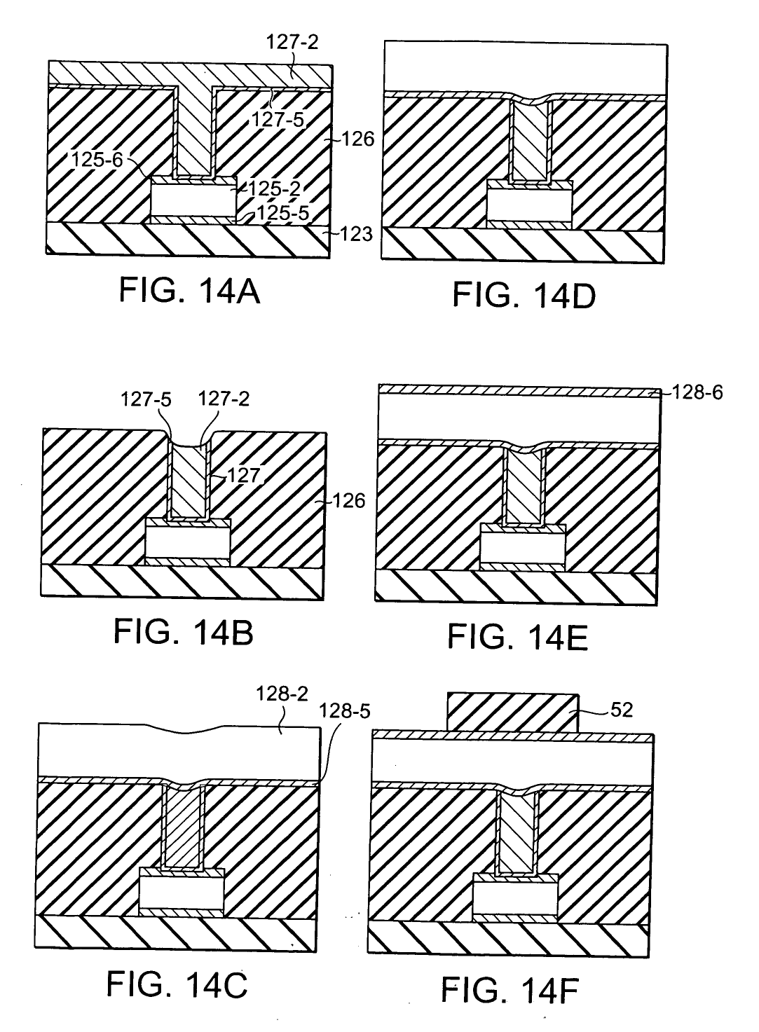

Next, the description will be made about a method for manufacturing multilevel wiring according to an eighth embodiment of this invention with reference to FIGS. 14A to 14F.

FIGS. 14A, 14B, and 14C correspond to FIGS. 5A, 5B and 5D. FIG. 14D shows a state after the AlCu film 128-2 shown in FIG. 14C is flattened. Moreover, FIGS. 14E and 14F correspond to FIGS. 5E and 5F.

The method of manufacturing the multilevel wiring according to the eighth embodiment is almost the same as the method according to the first embodiment. However, in the eighth embodiment, tantalum (Ta) is used for the wiring layer in place of titanium (Ti). That is, a tantalum (Ta) film can be formed by sputtering with introducing Ar gas and using tantalum as a target. In addition, a tantalum nitride (TaN) film can be formed by reactive sputtering with introducing Ar gas and nitrogen gas and using tantalum as a target.

In FIGS. 14A to 14D, the second wiring layer 125 composes of a TaN/Ta laminated film 125-5 (e.g. 30 nm/20 nm thickness), an AlCu film 125-2 (e.g. 270 nm thickness) and a TaN film 125-6 (e.g. 25 nm thickness).

Moreover, the third wiring layer 128 composes of a TaN/Ta film 128-5 (e.g. 30 nm/20 nm thickness), an AlCu film 128-2 (e.g. 600 nm thickness) and a TaN film 128-6 (e.g. 25 nm thickness).

In this embodiment, the upper surface of the third contact plug 127 is made to be almost the same level as the surface of the third interlayer insulation film 126. However, similarly as for the first embodiment, the upper portion of the third contact plug 127 may be projected from the surface of the third interlayer insulation film 126 to increase contact area between the third contact plug 127 and the third wiring layer 128.

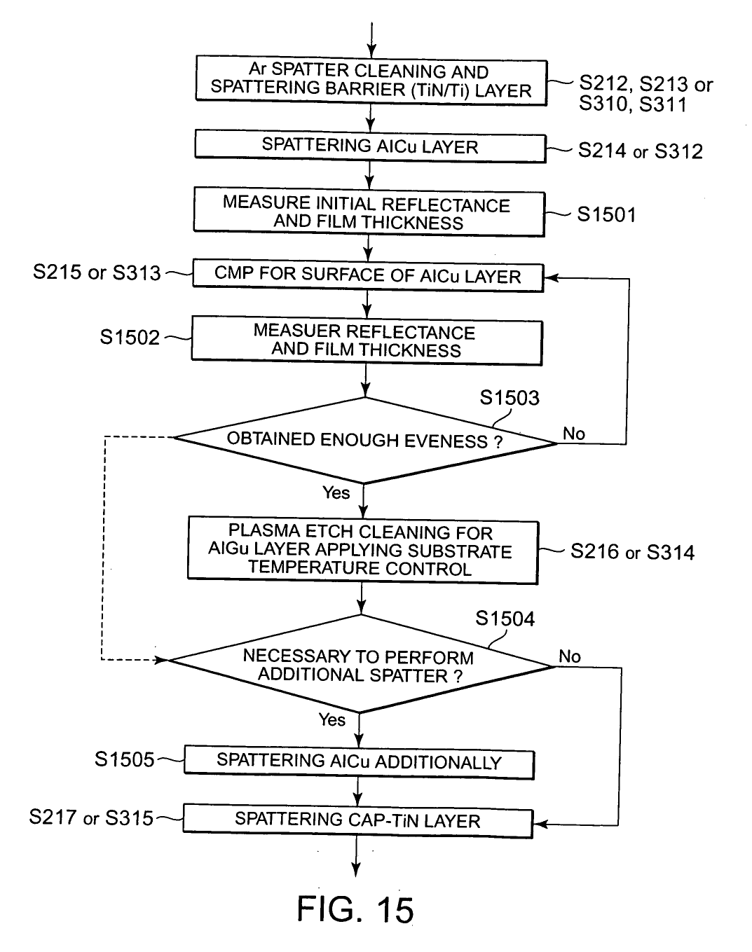

Next, the description will be made in detail about processes before and after the polishing (Step S215 or Step S313) of CMP method for the surface of the AlCu film in each of above mentioned embodiments with reference to FIG. 15.

After the AlCu film 125-2 or 128-2 is formed in step S214 or S312, an initial reflectance and a film thickness of the AlCu film are measured (Step S1501).

Next, in step S215 or S313, the AlCu film 125-2 or 128-2 is polished by CMP method to be removed by a predetermined thickness.

After that, a reflectance and a film thickness of the AlCu film 125-2 or 128-2 are measured again (Step S1502). Then, it is judged whether to have obtained a desired reflectance and a desired film thickness (Step S1503).

When the desired reflectance is not obtained as a result of the judgment, step S1503 goes back to step S215 or S313 to polish the surface of the AlCu film 125-2 and 128-2 again.

When it is judged that the desired reflectance and the desired film thickness are obtained in step S1503, step 1503 goes to step S216 or S314 to perform plasma etch cleaning for the surface of the AlCu film 125-2 or 128-2.

After plasma etch cleaning, the film thickness is measured again to judge whether the film thickness is equal to or larger than the desired thickness (Step S1504). When the film thickness is not enough, additional AlCu sputtering is performed according to insufficiency (Step S1505). When it is judged that the film thickness is equal to or larger than the desired thickness, step S1504 goes to step S217 or S315.

When it is judged that the desired reflectance is obtained but the film thickness is not enough in step S1503, step S1503 goes to step S1504 to perform the additional AlCu sputtering.

Incidentally, the production cost varies according to the number of times of the CMP and the number of times of AlCu sputtering. Therefore, it is necessary to decide criterions whether the CMP is repeated and/or whether the additional AlCu sputtering is performed according to desired production accuracy, appropriately. Moreover, the number of times of measurement of the reflectance and the film thickness may be reduced to a reasonable number for production stability.

According to each of the above mentioned embodiments, because the surface of the main metal wiring layer is flattened, appropriate exposure conditions for photo resist which is used to pattern the metal wiring layer are eased. Hereby, it is possible that the metal wiring layer is finely processed without influence of the contact plug under the metal wiring layer.

Furthermore, in a case where an antireflection film is provided between the metal wiring layer and the photo resist, the antireflection film can be formed uniformly for the reason mentioned above. Hereby, it is possible to process the metal wiring layer more finely.

Although the present invention has been described based on its preferred embodiments, it is to be understood that the present invention is not limited to the embodiments but may be otherwise variously embodied within the scope and spirit of the invention. These modifications and variations should be considered to be within the scope of the invention. For example, though the AlCu film is formed as the main wiring layer by sputtering in each embodiment mentioned above, aluminum or aluminum-based alloy (including aluminum of 50 weight % or more) may be used as a substitute for AlCu while formation method is not limited to the sputtering. For instance, an aluminum (AL) film may be formed by atomic layer (AL)-CVD method. The Al film can be flattened by CMP method and multilevel wiring may be formed by using the flattened Al film. It is also possible to combine parts of the above-mentioned embodiments with one another voluntarily.

1. A manufacturing method of multilevel wiring comprising:
forming a main wiring layer made of aluminum or aluminum-based alloy;
flattening a surface of the main wiring layer by means of CMP method; and
patterning the main wiring layer.

2. A manufacturing method as claimed in claim 1, further comprising:
forming a barrier metal layer consisting of one of a TiN film, a Tin/Ti laminated film, a TaN film and a TaN/Ta laminated film prior to the forming of the main wiring layer; and
patterning the barrier metal layer to have pattern approximately similar to that of the main wiring layer posterior to the patterning step of the main wiring layer.

3. A manufacturing method of multilevel wiring comprising:
forming a contact plug in a contact hole which is formed in an interlayer insulation film;
forming a barrier metal layer on both of the interlayer insulation film and the contact plug;
forming a main wiring layer made of aluminum or aluminum-based alloy on the barrier metal layer;
flattening a surface of the main wiring layer by means of CMP method; and
patterning the main wiring layer.

4. A manufacturing method as claimed in claim 3, wherein the forming of the contact plug comprises removing excess material for the contact plug by means of etch back method.

5. A manufacturing method as claimed in claim 3, further comprising:
etching a surface of the interlayer insulation film posterior to the forming of the contact plug.

6. A manufacturing method as claimed in claim 5, wherein the etching of the interlayer insulation film is performed to reduce level difference between an upper surface of the contact plug and the surface of the interlayer insulation film or to project an upper portion of the contact plug from the surface of the interlayer insulation film.

7. Multilevel wiring comprising:
an interlayer insulation film;
a contact plug formed in a contact hole which is formed in the interlayer insulation film; and
a main wiring layer made of aluminum or aluminum-based alloy and formed on both of the interlayer insulation film and the contact plug, wherein
a surface of the main wiring layer is flatten by means of CMP method and the main wiring layer is patterned.

8. Multilevel wiring claimed in claim 7, further comprising a barrier metal layer between the interlayer insulation film and the main wiring layer.

9. A manufacturing method of laminated aluminum wiring comprising:
forming a barrier metal layer;
forming a main wiring layer made of aluminum or aluminum-based alloy on the barrier metal layer;
flattening a surface of the main wiring layer;
forming a resist pattern on the main wiring layer; and
patterning the main wiring layer by use of the resist pattern.

10. A manufacturing method as claimed in claim 9, further comprising:
forming a cap layer between the main wiring layer and the resist pattern.

11. A manufacturing method as claimed in claim 10, wherein the cap layer comprises a TiN film or a TaN film.

12. A manufacturing method as claimed in claim 10, further comprising:
forming a hard mask layer which is an insulation film between the cap layer and the resist pattern.

13. A manufacturing method as claimed in claim 12, further comprising:
forming an antireflection film between the hard mask and the resist pattern.

14. Multilevel wiring comprising:
a barrier metal layer; and
a main wiring layer made of aluminum or aluminum-based alloy and formed on the barrier metal layer, wherein
a surface of the main wiring layer is flatten, and then
the main wiring layer is patterned by use of a resist pattern formed on the surface of the main wiring layer.

15. A manufacturing method of a semiconductor device comprising:
forming a contact plug in a contact hole which is formed in an interlayer insulation film;
etching the interlayer insulation film to project an upper portion of the contact plug from a surface of the interlayer insulation film;
forming a barrier metal layer on both of the interlayer insulation film and the contact plug;
forming a main wiring layer made of aluminum or aluminum-based alloy on the barrier layer; and
flattening a surface of the main wiring layer by means of CMP method.

16. A manufacturing method of a semiconductor device comprising:
forming a main wiring layer made of aluminum or aluminum based alloy;
measuring at least one reflectance of a surface of the main wiring layer and a film thickness of the main wiring layer;
judging whether it is necessary to flatten the main wiring layer according to measurement result;
flattening the surface of the main wiring layer when it is judged to be necessary.

17. A semiconductor device comprising:
a transistor at a surface of a semiconductor substrate;
an insulating film that is formed over said transistor, wherein said insulating film has a flattened surface; and
a wiring that has an aluminum or an aluminum alloy layer, wherein the surface of said aluminum or said aluminum-based alloy layer is flattened.

18. A semiconductor device as claimed in claim 17, further comprising:
said surface of said insulating film that is as flat as a level of CMP planarization;
said surface of said aluminum or said aluminum-based alloy layer that is as flat as a level of CMP planarization; and
a contact plug under said wiring.

19. Multilevel interconnection comprising:
a semiconductor substrate;
a plurality of wiring layers on said semiconductor substrate, wherein a wiring layer of said wiring layers has a flattened surface of a main conductive member; and
a contact plug which is connected to a part of said wiring layers.

20. A manufacturing method as claimed in claim 4, further comprising:
etching a surface of the interlayer insulation film posterior to the forming of the contact plug.
